(19) United States
(12) Patent Application Publication
(10) Pub. No.: US 2010/0208007 A1
(43) Pub. Date: Aug. 19, 2010

(54) PIEZOELECTRIC DEVICE, METHOD FOR PRODUCING PIEZOELECTRIC DEVICE, AND LIQUID DISCHARGE DEVICE

(76) Inventor: Yasukazu NIHEI, Kanagawa-ken (JP)

Correspondence Address: BIRCH STEWART KOLASCH & BIRCH, PO BOX 747, FALLS CHURCH, VA, 22040-0747, US

(21) Appl. No.: 12/707,815

(22) Filed: Feb. 18, 2010

(30) Foreign Application Priority Data
Feb. 19, 2009 (JP) 036075/2009

(51) Int. Cl. B41J 2/045; H01L 41/047; H01L 41/22

(52) U.S. Cl. 347/68; 310/365; 29/25.35

(57) ABSTRACT

A piezoelectric device of the present invention includes a piezoelectric material and lower and upper electrodes for applying an electric field to the piezoelectric material. The upper electrode is patterned, and an edge portion of the upper electrode is provided with a structure where an intensity of the electric field exerted on the piezoelectric material gradually decreases along a direction from a central portion toward an edge surface of the upper electrode when the electric field is applied to the piezoelectric material.

### BACKGROUND OF THE INVENTION

1. Field of the Invention

The present invention relates to a piezoelectric device, a method for producing the piezoelectric device, and a liquid discharge device.

2. Description of the Related Art

Piezoelectric devices, which include a piezoelectric material that expands or contracts when the intensity of an electric field applied thereto is increased or decreased and an electrode for applying the electric field to the piezoelectric material, are used as actuators, etc., provided in liquid discharge devices, such as inkjet recording heads. As piezoelectric materials, perovskite oxides, such as lead zirconium titanate (PZT), are known.

FIG. 8 shows a basic cross-sectional structure of a piezoelectric device. A piezoelectric device 200 includes a substrate 210, and a lower electrode 220, a piezoelectric material 230 and an upper electrode 240, which are formed in this order on the substrate 210. In conventional and typical piezoelectric devices, the lower electrode is formed over the entire surface of the substrate, and the upper electrode is formed in a predetermined pattern. In such a structure, electric charge tends to concentrate in the piezoelectric material in the vicinity of the edge surface of the upper electrode, and this may often cause a leakage current at this portion. Further, at the area where the upper electrode is formed, an electric field is applied to the piezoelectric material to cause displacement. In contrast, at the area where the upper electrode is not formed, the electric field is not exerted on the piezoelectric material in an active manner, and thus no active displacement occurs at this area. Therefore, stress also tends to concentrate in the piezoelectric material in the vicinity of the edge surface of the upper electrode. Portions where the electric charge and the stress tend to concentrate are indicated by the circles in the drawing.

Due to the high tendency of the concentration of electric charge and stress, microcracks may be generated in the piezoelectric material in the vicinity of the edge surface of the upper electrode. When the microcracks are generated in the surface of the piezoelectric material, moisture enters through these portions to cause deterioration of the piezoelectric material. In particular, operational durability of the piezoelectric material in a highly humid environment is lowered. This problem is prominent when the piezoelectric material is in the form of a thin film.

Japanese Unexamined Patent Publication No. 2008-147350 (which is herein after referred to as Patent Document 1) discloses a production method, wherein the upper electrode has a double-layer structure including a first upper electrode and a second upper electrode, which are formed in this order from the piezoelectric material side, the first upper electrode being formed through a sol-gel method or a MOD process and the second upper electrode being formed through a PVD process (claim 1).

Patent Document 1 teaches, in paragraph 0008, for example, that formation of a low dielectric layer at the upper electrode side of the piezoelectric material can be prevented, thereby preventing degradation of the displacement property of the piezoelectric material due to voltage drop caused by the low dielectric layer and deterioration of the leakage property, such as the concentration of electric charge at the low dielectric layer causing electric breakdown.

Patent Document 1 further teaches that it is preferred to form the piezoelectric material through the steps of coating a sol of an organic metal compound to form a piezoelectric material precursor film, and heating and firing the precursor film to form the piezoelectric film (claim 3), and that, when the first upper electrode is formed, it is preferred to form a first upper electrode precursor film, which will be the first upper electrode, on the piezoelectric material precursor film before being fired, and to simultaneously fire the piezoelectric material precursor film and the first upper electrode precursor film (claim 4). Patent Document 1 further teaches, in paragraph 0011, for example, that, according to this method, formation of a different phase between the piezoelectric material and the first upper electrode can be prevented, thereby preventing exfoliation due to the different phase and electric breakdown due to the concentration of electric charge.

The production method disclosed in Patent Document 1 is directed to preventing the exfoliation due to the different phase and the concentration of electric charge, and is not intended to minimize the concentration of electric charge in the piezoelectric material in the vicinity of the edge surface of the upper electrode.

Japanese Unexamined Patent Publication No. 2004-207633 (Patent Document 2) proposes a stacked piezoelectric device which has an edge portion of an internal electrode having a smoothly curved sectional shape without a corner (paragraph 0013, FIG. 2, etc.) Patent Document 2 teaches, in paragraph 0013, that this structure can minimize the concentration of electric charge at the edge portion of the internal electrode and can mitigate the concentration of stress in the vicinity of the edge portion of internal electrode of the piezoelectric material.

In the technique disclosed in Patent Document 2, the edge portion of the internal electrode is provided with the rounded shape in order to minimize the concentration of electric charge in the vicinity of the edge portion of the internal electrode of the stacked piezoelectric device. The technique does not minimize the concentration of electric charge in the vicinity of the edge surface of the upper electrode of typical piezoelectric devices, which are not stacked piezoelectric devices.

### SUMMARY OF THE INVENTION

In view of the above-described circumstances, the present invention is directed to providing a piezoelectric device with high durability, which is achieved by mitigating concentration of electric charge and stress in the piezoelectric material in the vicinity of an edge surface of an upper electrode, and a method for producing the piezoelectric device.

An aspect of the piezoelectric device of the invention includes a piezoelectric material and lower and upper electrodes for applying an electric field to the piezoelectric material, wherein the upper electrode is patterned, and an edge portion of the upper electrode is provided with a structure where an intensity of the electric field exerted on the piezoelectric material gradually decreases along a direction from a central portion toward an edge surface of the upper electrode when the electric field is applied to the piezoelectric material.

In a preferred first aspect of the piezoelectric device of the invention, a sloped-thickness insulating layer may be formed between the piezoelectric material and the edge portion of the upper electrode. The sloped-thickness insulating layer has a thickness that gradually increases along the direction from the central area toward the edge surface of the upper electrode.

The sloped-thickness insulating layer may be formed of a material having thickness-dependent permittivity.

The sloped-thickness insulating layer may be an organic insulating layer mainly composed of polyimide or an inorganic insulating layer mainly composed of a Si compound.

The description “mainly composed of” herein means that the content of the component(s) is not less than 90% by mass.

The piezoelectric device of the first aspect may be produced by a method including: step (A) of forming an unpatterned insulating layer on a substrate having the lower electrode and the piezoelectric material formed thereon; step (B) of forming a resist mask on the insulating layer at an area where the upper electrode is not to be formed; and step (C) of partially removing the insulating layer from an area where the upper electrode is to be formed to leave the insulating layer at an edge portion of the area where the upper electrode is to be formed, the left insulating layer having a thickness that gradually increases along the direction from the central area toward the edge surface of the upper electrode, thereby forming the sloped-thickness insulating layer.

The step (C) may include partially removing the insulating layer from the area where the upper electrode is to be formed through a dry etching process.

In a preferred second aspect of the piezoelectric device of the invention, the edge portion of the upper electrode may have a gradient composition structure where an insulation property of the upper electrode gradually becomes higher along the direction from the central area toward the edge surface of the upper electrode.

In the second aspect, a main portion other than the edge portion of the upper electrode may be mainly composed of a conductive metal, and the edge portion of the upper electrode may have a gradient composition structure where a metal oxide content gradually increases along the direction from the central area toward the edge surface of the upper electrode.

The piezoelectric device of the second aspect may be produced by a method including: step (D) of forming the upper electrode having a uniform composition mainly composed of a conductive metal on a substrate having the lower electrode and the piezoelectric material formed thereon; step (E) of forming an oxygen permeating film on the upper electrode, the oxygen permeating film having such oxygen permeability that an area of the oxygen permeating film corresponding to the main portion other than the edge portion of the upper electrode has a uniform oxygen transmission rate, and an area of the oxygen permeating film corresponding to the edge portion of the upper electrode has an oxygen transmission rate that gradually increases along the direction from the central area toward the edge surface of the upper electrode; and step (F) of applying oxidation to the upper electrode covered with the oxygen permeating film to provide the edge portion of the upper electrode with the gradient composition structure.

The step (E) may include forming, as the oxygen permeating film, an oxygen permeating film having a sloped-thickness structure where an area corresponding to the main portion other than the edge portion of the upper electrode has a uniform thickness, and an area corresponding to the edge portion of the upper electrode has a thickness that gradually decreases along the direction from the central area toward the edge surface of the upper electrode.

The oxygen permeating film may be a film having an oxygen permeability coefficient at a temperature of 40° C. of not less than 1.0×10⁻¹¹ (cm³(STP)·cm/cm²·s·cmHg).

The oxygen permeability coefficient herein is data at a temperature of 40° C., unless otherwise stated.

The piezoelectric device of the second aspect may be produced by a method including: step (D) of forming the upper electrode having a uniform composition mainly composed of a conductive metal on a substrate having the lower electrode and the piezoelectric material formed thereon; step (G) of forming a covering film on the upper electrode; and step (H) of applying oxidation to the upper electrode covered with the covering film from an edge surface side of the upper electrode to provide the edge portion of the upper electrode with the gradient composition structure.

A first aspect of the method for producing a piezoelectric device is a method for producing the piezoelectric device of the first aspect. The method includes: step (A) of forming an unpatterned insulating layer on a substrate having the lower electrode and the piezoelectric material formed thereon; step (B) of forming a resist mask on the insulating layer at an area where the upper electrode is not to be formed; and step (C) of partially removing the insulating layer from an area where the upper electrode is to be formed to leave the insulating layer at an edge portion of the area where the upper electrode is to be formed, the left insulating layer having a thickness that gradually increases along the direction from the central area toward the edge surface of the upper electrode, thereby forming the sloped-thickness insulating layer.

A second aspect of the method for producing a piezoelectric device of the invention is a method for producing the piezoelectric device of the second aspect. The method includes: step (D) of forming the upper electrode having a uniform composition mainly composed of a conductive metal on a substrate having the lower electrode and the piezoelectric material formed thereon; step (E) of forming an oxygen permeating film on the upper electrode, the oxygen permeating film having such oxygen permeability that an area of the oxygen permeating film corresponding to the main portion other than the edge portion of the upper electrode has a uniform oxygen transmission rate, and an area of the oxygen permeating film corresponding to the edge portion of the upper electrode has an oxygen transmission rate that gradually increases along the direction from the central area toward the edge surface of the upper electrode; and step (F) of applying oxidation to the upper electrode covered with the oxygen permeating film to provide the edge portion of the upper electrode with the gradient composition structure.

A third aspect of the method for producing a piezoelectric device of the invention is a method for producing the piezoelectric device of the second aspect. The method includes: step (D) of forming the upper electrode having a uniform composition mainly composed of a conductive metal on a substrate having the lower electrode and the piezoelectric material formed thereon; step (G) of forming a covering film on the upper electrode; and step (H) of applying oxidation to the upper electrode covered with the covering film from an edge surface side of the upper electrode to provide the edge portion of the upper electrode with the gradient composition structure.

The liquid discharge device of the invention includes: the piezoelectric device of the invention; and a liquid discharge member disposed adjacent to the piezoelectric device, the liquid discharge member including a liquid reservoir for storing a liquid, and a liquid discharge port for discharging the liquid from the liquid reservoir to the outside in response to application of the electric field to the piezoelectric film.

According to the invention, a piezoelectric device with high durability, which is achieved by mitigating concentration of electric charge and stress in the piezoelectric material in the vicinity of an edge surface of an upper electrode, and a method for producing the piezoelectric device can be provided.

According to the invention, a piezoelectric device with good durability in a high temperature and high humidity environment at a temperature of 40° C. and a relative humidity of 80% and a method for producing the piezoelectric device can be provided.

### BRIEF DESCRIPTION OF THE DRAWINGS

FIG. 1 is a sectional view illustrating the structures of a piezoelectric device and an inkjet recording head according to a first embodiment of the invention,

FIGS. 2A to 2F illustrates a production process for producing the piezoelectric device shown in FIG. 1,

FIG. 3 is a sectional view illustrating the structures of a piezoelectric device and an inkjet recording head according to a second embodiment of the invention,

FIGS. 4A to 4F illustrates a production process for producing the piezoelectric device shown in FIG. 3,

FIGS. 5A to 5F illustrates another production process for producing the piezoelectric device shown in FIG. 3,

FIG. 6 is a diagram illustrating a configuration example of an inkjet recording device including the inkjet recording head shown in FIG. 1 or 3,

FIG. 7 is a partial plan view of the inkjet recording device shown in FIG. 6, and

FIG. 8 is a sectional view illustrating a basic structure of a conventional piezoelectric device.

### DESCRIPTION OF THE PREFERRED EMBODIMENTS

### First Embodiment of Piezoelectric Device and Inkjet Recording Head

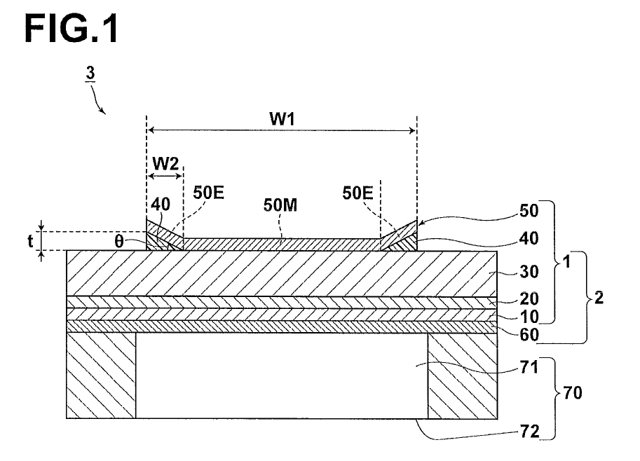

The structures of a piezoelectric device and an inkjet recording head (liquid discharge device) including the piezoelectric device according to a first embodiment of the invention are described with reference to FIG. 1. FIG. 1 is a sectional view of the main portion of the inkjet recording head (a sectional view along the thickness direction of the piezoelectric device). For ease of visual understanding, the components shown in the drawing are not to scale.

A piezoelectric device 1 of this embodiment includes a substrate 10, and a lower electrode 20, a piezoelectric material 30 and an upper electrode 50, which are formed in this order on the substrate 10. An electric field in the thickness direction is applied to the piezoelectric material 30 via the lower electrode 20 and the upper electrode 50.

The lower electrode 20 and the piezoelectric material 30 are formed over substantially the entire surface of the substrate 10. On the piezoelectric material 30, the upper electrode 50 is patterned. The piezoelectric material 30 may also be patterned. When the piezoelectric material 30 is formed in a pattern including a plurality of separate protrusions, the individual protrusions can smoothly expand or contract, thereby preferably providing a larger displacement.

In this embodiment, a sloped-thickness insulating layer 40 is formed between the piezoelectric material 30 and an edge portion 50E of the upper electrode 50. The sloped-thickness insulating layer 40 has a thickness that gradually increases along a direction from the central area toward the edge surface of the upper electrode.

The substrate 10 is not particularly limited, and may be any substrate, such as a silicon, silicon oxide, stainless steel (SUS), yttrium stabilized zirconia (YSZ), alumina, sapphire, SiC, or SrTiO₃ substrate. The substrate 10 may be a multilayer substrate, such as a SOI substrate including a SiO₂ film and a Si active layer formed in this order on a silicon substrate.

The composition of the lower electrode 20 is not particularly limited, and examples thereof may include a metal or a metal oxide, such as Au, Pt, Ir, IrO₂, RuO₂, LaNiO₃, and SrRuO₃, as well as combinations thereof. The composition of the upper electrodes 50 is not particularly limited, and examples thereof may include the example materials listed for the lower electrode 20, electrode materials commonly used in semiconductor processes, such as Al, Ta, Cr and Cu, and combinations thereof. The thicknesses of the lower electrode 20 and the upper electrodes 50 are not particularly limited; however, their thicknesses may be in the range from 50 to 500 nm.

A piezoelectric actuator 2 includes a vibrating plate 60, which vibrates along with expansion and contraction of the piezoelectric material 30, attached on the back side of the substrate 10 of the piezoelectric device 1. The piezoelectric actuator 2 also includes a controlling means (not shown), such as a drive circuit, for controlling drive of the piezoelectric device 1.

An inkjet recording head (liquid discharge device) 3 generally includes, at the back side of the piezoelectric actuator 2, an ink nozzle (liquid storing and discharging member) 70 including an ink chamber (liquid reservoir) 71 for storing ink and an ink discharge port (liquid discharge port) 72 through which the ink is discharged from the ink chamber 71 to the outside. In the inkjet recording head 3, the piezoelectric device 1 expands or contracts when the intensity of the electric field applied to the piezoelectric device 1 is increased or decreased, thereby controlling discharge of the ink from the ink chamber 71 and the amount of the discharged ink.

Instead of providing the vibrating plate 60 and the ink nozzle 70 which are members separate from the substrate 10, parts of the substrate 10 may be machined to form the vibrating plate 60 and the ink nozzle 70. For example, if the substrate 10 is a multilayer substrate, such as a SOI substrate, the substrate 10 may be etched at the back side thereof to form the ink chamber 71, and then the substrate may be machined to form the vibrating plate 60 and the ink nozzle 70.

The piezoelectric material 30 may take any form, such as a single crystal, a bulk ceramic or a film. Considering providing a thinner and smaller piezoelectric device 1 and productivity, etc., the piezoelectric material 30 may take the form of a film, and may optionally be a thin film with a thickness in the range from 10 nm to 100 μm, or further optionally be a thin film with a thickness in the range from 100 nm to 20 μm.

The process used to form the piezoelectric material 30 is not particularly limited, and examples thereof include gas phase processes, such as sputtering, plasma CVD, MOCVD and PLD; liquid phase processes, such as sol-gel method and organic metal decomposition method; and aerosol deposition process.

The composition of the piezoelectric material 30 is not particularly limited; however, the piezoelectric material 30 may be formed by one or two or more perovskite oxides (which may contain inevitable impurities) represented by the formula (P) below:

ABO₃ General Formula (P)

(wherein A represents an A-site element and includes at least one element selected from the group consisting of Pb, Ba, Sr, Bi, Li, Na, Ca, Cd, Mg, K and lanthanide elements; B represents a B-site element and includes at least one element selected from the group consisting of Ti, Zr, V, Nb, Ta, Cr, Mo, W, Mn, Mg, Sc, Co, Cu, In, Sn, Ga, Zn, Cd, Fe, Ni, Hf and Al; O is oxygen; and a molar ratio of A-site element:B-site element:oxygen element is 1:1:3 as a standard; however, the molar ratio may be varied from the standard molar ratio within a range where a perovskite structure is obtained.)

Examples of the perovskite oxides represented by general formula (P) include: lead-containing compounds, such as lead titanate, lead zirconate titanate (PZT), lead zirconate, lead lanthanum titanate, lead lanthanum zirconate titanate, lead magnesium niobate zirconium titanate, lead nickel niobate zirconium titanate and lead zinc niobate zirconium titanate, as well as mixed crystal systems thereof; and non-lead-containing compounds, such as barium titanate, strontium barium titanate, bismuth sodium titanate, bismuth potassium titanate, sodium niobate, potassium niobate and lithium niobate, as well as mixed crystal systems thereof.

In view of improvement of electrical characteristics, the perovskite oxide represented by general formula (P) may contain one or two or more metal ions, such as Mg, Ca, Sr, Ba, Bi, Nb, Ta, W, and Ln (=lanthanide elements: La, Ce, Pr, Nd, Sm, Eu, Gd, Tb, Dy, Ho, Er, Tm, Yb, and Lu).

As described above, in this embodiment, the sloped-thickness insulating layer 40, which has a thickness that gradually increases along the direction from the central area toward the edge surface of the upper electrode, is formed between the piezoelectric material 30 and the edge portion 50E of the upper electrode 50. With this structure, a distance between the lower electrode 20 and the upper electrode 50 at the area corresponding to the edge portion 50E of the upper electrode 50 gradually increases along the direction from the central area toward the edge surface of the upper electrode. Therefore, at the area corresponding to the edge portion 50E of the upper electrode 50, when an electric field is applied to the piezoelectric material 30, intensity of the electric field exerted on the piezoelectric material 30 gradually decreases along the direction from the central area toward the edge surface of the upper electrode.

The composition of the sloped-thickness insulating layer 40 is not particularly limited, and the layer may be an organic insulating layer or an inorganic insulating layer. An electric field E1 induced when a dielectric material having a relative permittivity ε is inserted between electrodes with an electric field E is expressed by the equation below:

E1=E/ε0

The sloped-thickness insulating layer 40 may be formed of a material having a thickness-dependent permittivity. Some reports have been made about change of permittivity of polymeric thin films depending on the film thickness, and it is reported that the permittivity exhibits the film thickness dependency within the range of the thickness of a polymeric film of not more than about 1.0 μm (“Effect of Film Thickness on Electrical Properties of Polyimide Thin Films”, T. Liang et al., JSR TECHNICAL REVIEW, No. 109, pp. 6-11, 2002, etc.)

That is, the sloped-thickness insulating layer 40 may be one of various polymeric films. Considering that the upper electrode 50 is formed after the sloped-thickness insulating layer 40 has been formed, the sloped-thickness insulating layer 40 may be a polymeric film with high heat resistance. Optionally, the sloped-thickness insulating layer 40 may be an organic insulating layer mainly composed of polyimide. Further, a maximum film thickness t of the sloped-thickness insulating layer 40 may be in the range of not more than 1.0 μm, where the permittivity of the layer exhibits the film thickness dependency.

Si compounds, such as SiO₂ and Si₃N₄, also have a permittivity that exhibits the film thickness dependency in the range of the film thickness of not more than about 1.0 μm. The sloped-thickness insulating layer 40 may be an inorganic insulating layer mainly composed of one or two or more Si compounds. Also in this case, the maximum film thickness t of the sloped-thickness insulating layer 40 may be in the range of not more than 1.0 μm, where the permittivity of the layer exhibits the film thickness dependency.

With the sloped-thickness insulating layer 40 formed of a material having thickness-dependent permittivity being provided at the area corresponding to the edge portion 50E of the upper electrode 50, the structure where the intensity of the electric field exerted on the piezoelectric material 30 gradually decreases along the direction from the central area toward the edge surface of the upper electrode, when the electric field is applied to the piezoelectric material 30, can successfully be formed at the area corresponding to the edge portion 50E of the upper electrode 50.

With the structure of this embodiment, at the area corresponding to the edge portion 50E of the upper electrode 50, the intensity of the electric field exerted on the piezoelectric material 30 gradually decreases along the direction from the central area toward the edge surface of the upper electrode when the electric field is applied to the piezoelectric material 30, and therefore, the piezoelectric displacement of the piezoelectric material 30 also gradually decreases along the direction from the central area toward the edge surface of the upper electrode. Thus, with the structure of this embodiment, the concentration of electric charge and stress in the piezoelectric material 30 in the vicinity of the edge surface of the upper electrode 50 can be mitigated.

An area W2 where the sloped-thickness insulating layer 40 is formed and a slope angle θ are not particularly limited. In this embodiment, the electric field is applied to the piezoelectric material 30 and the piezoelectric displacement occurs mainly at the area corresponding to a main portion 50M other than the edge portion 50E of the upper electrode 50. If the area W2 is excessively large, satisfactory piezoelectric displacement occurs only in a small area. Therefore, the area W2 may be designed as small as possible within a range where the effect of mitigating the concentration of electric charge and stress in the piezoelectric material 30 in the vicinity of the edge surface of the upper electrode 50 can be provided.

The area W2 may be not more than 5% of a width W1 of the upper electrode 50 (i.e., the total width W2 of the sloped-thickness insulating layer 40 at the opposite edge portions may be not more than 10% of the width W1). The smaller the slope angle θ of the sloped-thickness insulating layer 40, the smaller the gradient of the change of the intensity of the electric field. The slope angle θ may be not more than 60°, optionally not more than 45°, or further optionally not more than 30°. With a smaller slope angle θ, a ratio of the area W2 where the sloped-thickness insulating layer 40 is formed to the width W1 of the upper electrode is increased. Therefore, a smaller angel θ may be selected within the range where the ratio of W2/W1 is not more than 5%.

The structures of the piezoelectric device 1 and the inkjet recording head 3 of this embodiment are as described above. According to this embodiment, the concentration of electric charge and stress in the piezoelectric material 30 in the vicinity of the edge surface of the upper electrode 50 can be mitigated, thereby providing the piezoelectric device 1 with high durability. According to this embodiment, the piezoelectric device 1 with good durability even in a high temperature and high humidity environment at a temperature of 40° C. and a relative humidity of 80% can be provided.

### Method for Producing Piezoelectric Device of First Embodiment

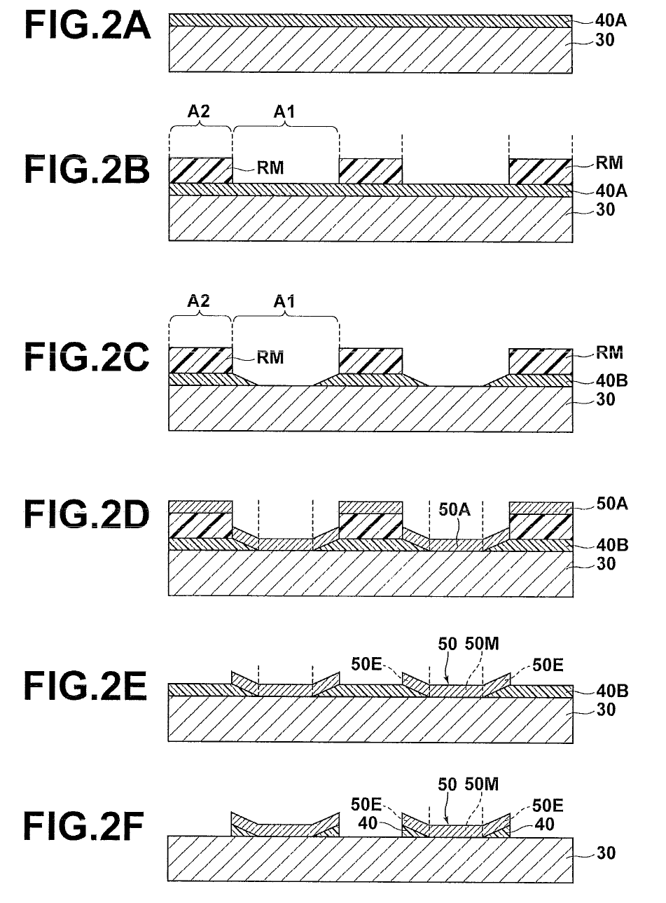

An example of a method for producing the piezoelectric device of the first embodiment is described with reference to the drawings. FIGS. 2A to 2F illustrate a production process. The substrate 10 and the lower electrode 20 are not shown in these drawings.

First, the lower electrode 20 and the piezoelectric material 30 are formed on the substrate 10 using a conventional process (not shown). Then, as shown in FIG. 2A, a film of a material of the sloped-thickness insulating layer 40 is formed on the piezoelectric material 30 to form an unpatterned insulating layer 40A (step (A)).

If the insulating layer 40A is formed of an organic material, the insulating layer 40A may be formed, for example, through a process including preparing a solution containing the organic material dissolved in a solvent, coating the solution on the piezoelectric material 30 using any of various coating method, such as spin coating and dip coating, or one of various printing processes, such as screen printing, and drying the coated solution to remove the solvent. If the insulating layer 40A is a polyimide film, the film may be formed using a polyamic acid, which is the precursor, and then removal of the solvent and imidization may be achieved through heating.

If the insulating layer 40A is formed of an organic material, examples of the process used to form the insulating layer 40A may include gas phase processes, such as sputtering, CVD, and vapor deposition; and chemical liquid phase processes, such as sol-gel method and MOD (metal organic deposition).

Then, as shown in FIG. 2B, a resist mask RM is formed at an area A2, where the upper electrode 50 is not to be formed, on the insulating layer 40A (step (B)). In the drawing, the symbol A1indicates an area where the upper electrode 50 is to be formed.

Then, as shown in FIG. 2C, the insulating layer 40A is partially removed from the area A1 where the upper electrode 50 is to be formed, so that the insulating layer having a thickness that gradually increases along the direction from the central area toward the edge surface of the upper electrode is left to form the sloped-thickness insulating layer 40 at the edge portion of the area A1 (step (C)). In the drawings, the symbol 40B indicates the insulating layer after step (C).

Examples of the process used to partially remove the insulating layer 40A from the area A1 where the upper electrode 50 is to be formed may include dry etching and wet etching, and in particular, dry etching may be used. The area W2 where the sloped-thickness insulating layer 40 is formed and the slope angle θ can be controlled by controlling the thickness of the resist mask RM and etching conditions.

Although the dry etching is known as an anisotropic etching process, the area W2 where the sloped-thickness insulating layer 40 is formed and the slope angle θ can be controlled by forming the resist mask RM having a relatively large thickness and controlling collision of gas molecules against the insulating layer 40A to be close to that of isotropic etching with utilizing the shadow of the resist mask RM. Although the thickness of the resist mask in conventional dry etching processes is on the order of several micrometers, the thickness of the resist mask RM in this embodiment may, for example, be about 3 to 10 μm.

Then, as shown in FIG. 2D, a film of a material of the upper electrode 50 is formed on the substrate 10, which has the insulating layer 40B formed thereon, to form an unpatterned upper electrode 50A. Then, as shown in FIG. 2E, the resist mask RM and the upper electrode 50A formed on the resist mask RM are removed through a liftoff process.

Finally, as shown in FIG. 2F, the insulating layer 40B at the area A2 where the upper electrode 50 is not formed is removed through etching. In this manner, piezoelectric device 1 of the above-described embodiment is produced. The step shown in FIG. 2F may not be carried out since there is no problem if the insulating layer 40B is left at the area A2 where the upper electrode 50 is not formed. It should be noted that the method for producing the piezoelectric device of the first embodiment is not limited to the above-described process, and may be modified as appropriate.

### Second Embodiment of Piezoelectric Device and Inkjet Recording Head

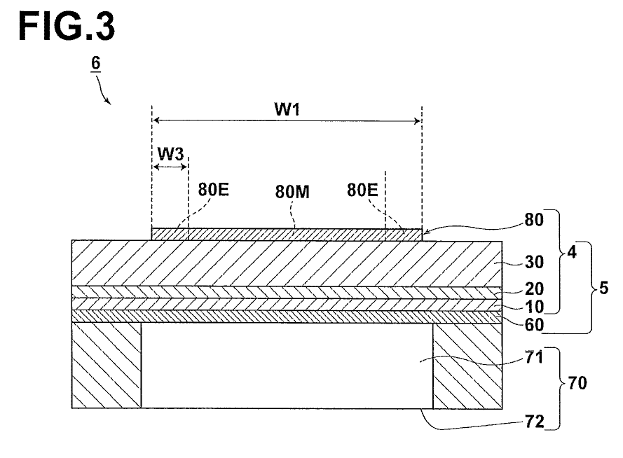

The structures of a piezoelectric device and an inkjet recording head (liquid discharge device) including the piezoelectric device according to a second embodiment of the invention are described with reference to FIG. 3. FIG. 3 is a sectional view illustrating the main portion of the inkjet recording head (a sectional view taken along the thickness direction of the piezoelectric device). For ease of visual understanding, the components shown in the drawing are not to scale. Components that are the same as those in the first embodiment are denoted by the same reference symbols, and explanation thereof is omitted.

A piezoelectric device 4 of this embodiment includes the substrate 10, and the lower electrode 20, the piezoelectric material 30 and an upper electrode 80 which are sequentially formed on the substrate 10. An electric field in the thickness direction is applied to the piezoelectric material 30 via the lower electrode 20 and the upper electrode 80. Similarly to the first embodiment, the lower electrode 20 and the piezoelectric material 30 are formed over substantially the entire surface of the substrate 10, and the upper electrode 80 is patterned on the piezoelectric material 30.

In this embodiment, the sloped-thickness insulating layer 40 is not provided, and an edge portion 80E of the upper electrode 80 has a gradient composition structure, where the insulation property of the upper electrode 80 gradually becomes higher along the direction from the central area toward the edge surface of the upper electrode.

The gradient composition structure may be such that a main portion 80M other than the edge portion 80E of the upper electrode 80 mainly composed of a conductive metal, whereas the edge portion 80E of the upper electrode 80 has the gradient composition structure where a metal oxide content gradually increases along the direction from the central area toward the edge surface of the upper electrode.

In view of ease of providing an oxide, the main component of the main portion 80M of the upper electrode 80 may be one or tow or more conductive metals, such as Ir, Al, Ta, Cr, Ti, Zn, Sn and Cu. The thickness of the upper electrode 80 is not particularly limited; however, the thickness may be in the range from 50 to 500 nm.

A piezoelectric actuator 5 includes the vibrating plate 60, which is attached on the back side of the substrate 10 of the piezoelectric device 4. An inkjet recording head (liquid discharge device) 6 includes the ink nozzle (liquid storing and discharging member) 70, which is attached on the back side of the piezoelectric actuator 5.

In this embodiment, the edge portion 80E of the upper electrode 80 has the gradient composition structure where the insulation property of the upper electrode 80 gradually becomes higher along the direction from the central area toward the edge surface of the upper electrode. Therefore, at the area corresponding to the edge portion 80E of the upper electrode 80, the intensity of the electric field exerted on the piezoelectric material 30 gradually decreases along the direction from the central area toward the edge surface of the upper electrode when the electric field is applied to the piezoelectric material 30, and therefore, the piezoelectric displacement of the piezoelectric material 30 gradually decreases along the direction from the central area toward the edge surface of the upper electrode. Thus, with the structure of this embodiment, the concentration of electric charge and stress in the piezoelectric material 30 in the vicinity of the edge surface of the upper electrode 80 can be mitigated.

An area W3 where the gradient composition structure is formed is not particularly limited. In this embodiment, the electric field is applied to the piezoelectric material 30 and the piezoelectric displacement occurs mainly at the area corresponding to the main portion 80M of the upper electrode 80 other than the edge portion 80E. If the area W3 is excessively large, satisfactory piezoelectric displacement occurs only in a small area. Therefore, the area W3 may be designed as small as possible within a range where the effect of mitigating the concentration of electric charge and stress in the piezoelectric material 30 in the vicinity of the edge surface of the upper electrode 80 can be provided. The area W3 may be not more than 5% of a width W1 of the upper electrode 80 (i.e., the total width W3 of the gradient composition structure at the opposite edge portions may be not more than 10% of the width W1).

The structures of the piezoelectric device 4 and the inkjet recording head 6 of this embodiment are as described above. According to this embodiment, the concentration of electric charge and stress in the piezoelectric material 30 in the vicinity of the edge surface of the upper electrode 80 can be mitigated, thereby providing the piezoelectric device 4 with high durability. According to this embodiment, the piezoelectric device 4 with good durability in a high temperature and high humidity environment at a temperature of 40° C. and a relative humidity of 80% can be provided.

### Method for Producing Piezoelectric Device of Second Embodiment

An example of a method for producing the piezoelectric device of the second embodiment is described with reference to the drawings.

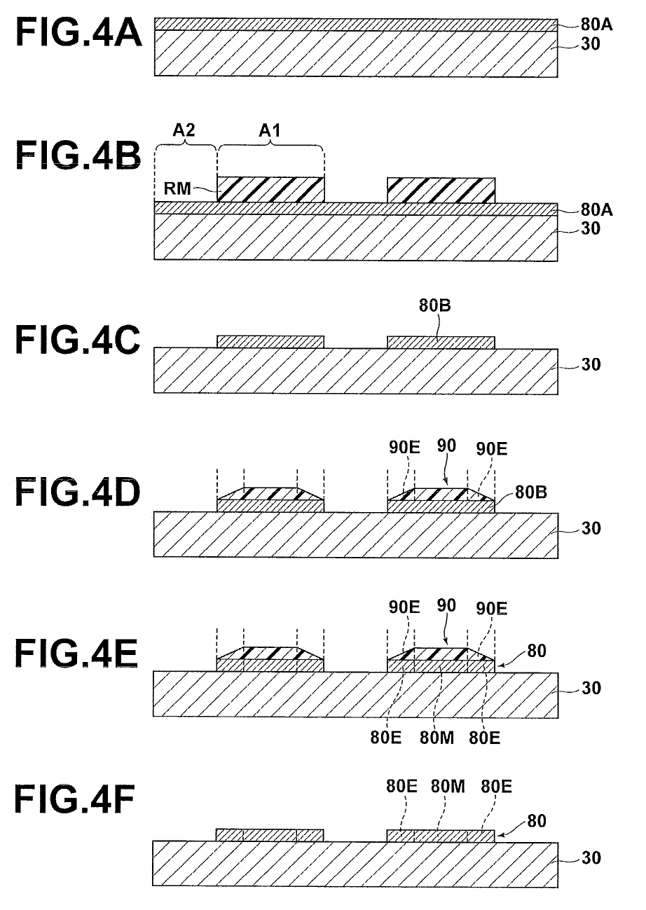

FIGS. 4A to 4F illustrate a production process. The substrate 10 and the lower electrode 20 are not shown in these drawings.

First, the lower electrode 20 and the piezoelectric material 30 are formed on the substrate 10 using a conventional process (not shown). Then, as shown in FIG. 4A, a film of a material of the main portion 80M of the upper electrode 80 is formed on the piezoelectric material 30 to form an unpatterned upper electrode 80A having a uniform composition which is mainly composed of a conductive metal. The process used to form the upper electrode 80A is not particularly limited, and examples thereof may include gas phase processes, such as sputtering, CVD, and vapor deposition; and chemical liquid phase processes, such as sol-gel method and MOD (metal organic deposition).

Then, as shown in FIG. 4B, the resist mask RM is formed at the area A1 where the upper electrode 80 is to be formed. Then, as shown in FIG. 4C, patterning of the upper electrode 80A and removal of the resist mask RM are carried out to form a patterned upper electrode 80B having the uniform composition and mainly composed of the conductive metal (step (D)).

Then, as shown in FIG. 4D, an oxygen permeating film 90 is formed on the upper electrode 80B (step (E)). The oxygen permeating film 90 has such oxygen permeability that an area of the oxygen permeating film corresponding to the main portion 80M of the upper electrode 80 has a uniform oxygen transmission rate, and an area of the oxygen permeating film corresponding to the edge portion 80E of the upper electrode 80 has an oxygen transmission rate that gradually increases along the direction from the central area toward the edge surface of the upper electrode.

The oxygen permeating film 90 having the above-described oxygen permeability may be an oxygen permeating film having a sloped-thickness structure where the area corresponding to the main portion 80M of the upper electrode 80 has a uniform thickness and the area corresponding to the edge portion 80E of the upper electrode 80 has a thickness that gradually decreases along the direction from the central area toward the edge surface of the upper electrode. In the drawing, the symbol 90M indicates the main portion of the oxygen permeating film 90 having a uniform thickness, and the symbol 90E indicates the edge portion of the oxygen permeating film 90 having the sloped-thickness structure where the thickness gradually decreases along the direction from the central area toward the edge surface of the upper electrode.

The oxygen permeating film having the sloped-thickness structure can be formed by, first, forming an oxygen permeating film having a uniform thickness, and then, partially removing the formed film. Examples of the process used to partially remove the oxygen permeating film may include dry etching and wet etching, and in particular, dry etching may be used. The area where the sloped-thickness structure is formed and the slope angle can be controlled by controlling the thickness of the resist mask RM and etching conditions.

Although the dry etching is known as an anisotropic etching process, the area where the sloped-thickness structure is formed and the slope angle can be controlled by forming the resist mask having a relatively large thickness and controlling collision of gas molecules against the oxygen permeating film to be close to that of isotropic etching with utilizing the shadow of the resist mask. Although the thickness of the resist mask in conventional dry etching processes is on the order of several micrometers, the thickness of the resist mask in this embodiment may, for example, be about 3 to 10 μm.

The composition of the oxygen permeating film 90 is not particularly limited, and the oxygen permeating film 90 may be any polymeric film or an inorganic film, such as a gas-permeable porous ceramic film. Any of polymeric films is oxygen permeable due to the free volume of polymers.

In view of ease of oxidation of the edge portion of the upper electrode 80B in the subsequent step, the oxygen permeating film 90 may have an oxygen permeability coefficient at 40° C. of not less than 1.0×10⁻¹¹ (cm³(STP)·cm/cm²·s·cmHg). Examples of the oxygen permeating film 90 having the oxygen permeability in this range may include polyethylene film (for example, 1.5×10⁻¹⁰ (cm³(STP)·cm/cm²·s·cmHg), silicone film (for example, 5.0×10⁻⁸ (cm³(STP)·cm/cm²·s·cmHg) and silicone polycarbonate film (for example, 7.5×10⁻¹¹ (cm³(STP)·cm/cm²·s·cmHg). The data of the oxygen permeability coefficients here is found in “Polymer Handbook”.

The maximum film thickness of the oxygen permeating film 90 is not particularly limited, and is designed as appropriate depending on the oxygen permeability coefficient. The maximum film thickness of the oxygen permeating film 90 may, for example, in the range from about 100 to 500 μm.

If the oxygen permeating film 90 is a polymeric film, the oxygen permeating film 90 may be formed, for example, through a process including preparing a solution containing the polymer dissolved in a solvent, coating the solution on the upper electrode 80B using one of various printing processes, such as screen printing, and drying the coated solution to remove the solvent. A polymer precursor may be used to form the coated film.

If the oxygen permeating film 90 is an inorganic film, examples of the process used to form the oxygen permeating film 90 may include gas phase processes, such as sputtering, CVD, and vapor deposition; and chemical liquid phase processes, such as sol-gel method and MOD (metal organic deposition).

Then, as shown in FIG. 4E, the upper electrode 80B covered with the oxygen permeating film 90 is oxidized to provide the edge portion 80E of the upper electrode 80B with the gradient composition structure (step (F)).

The oxidation may be achieved by heating under the presence of oxygen, such as oxygen or air, for example. The heating temperature and the oxidation time are not particularly limited, and may be designed as appropriate within a range where sufficient oxidation of the edge portion 80E of the upper electrode 80B is achieved, depending on the oxygen concentration in the atmosphere as well as the oxygen permeability coefficient and the film thickness of the oxygen permeating film 90. The heating temperature may, for example, be in the range from 50 to 100° C. The oxidation time may be in the range from 1 to 24 hours.

Finally, as shown in FIG. 4F, the oxygen permeating film 90 is removed. In this manner, the piezoelectric device 4 of the above-described embodiment is produced. If the organic oxygen permeating film 90 is an organic film, the removal of the organic oxygen permeating film 90 may be achieved by dissolving the film with a solvent. If the organic oxygen permeating film 90 is an inorganic film, the inorganic oxygen permeating film 90 may be removed through dry etching or wet etching.

### Another Method for Producing Piezoelectric Device of Second Embodiment

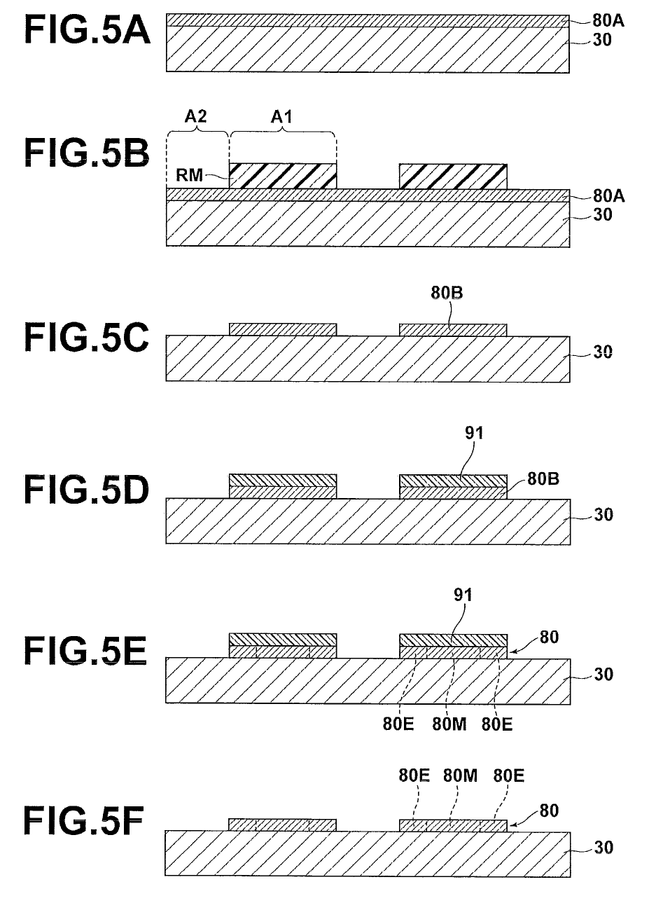

An example of another method for producing the piezoelectric device of the second embodiment is described with reference to the drawings. FIGS. 5A to 5F illustrate a production process. The substrate 10 and the lower electrode 20 are not shown in these drawings.

First, the lower electrode 20 and the piezoelectric material 30 are formed on the substrate 10 using a conventional process (not shown). Then, as shown in FIG. 5A, a film of a material of the main portion 80M of the upper electrode 80 is formed on the piezoelectric material 30 to form an unpatterned upper electrode 80A having a uniform composition which is mainly composed of a conductive metal.

Then, as shown in FIG. 5B, the resist mask RM is formed at the area A1 where the upper electrode 80 is to be formed. Then, as shown in FIG. 5C, patterning of the upper electrode 80A and removal of the resist mask RM are carried out to form a patterned upper electrode 80B having the uniform composition and mainly composed of the conductive metal (step (D)).

Then, as shown in FIG. 5D, a covering film 91 is formed on the upper electrode 80B (step (G)). In this embodiment, the upper electrode 80B is oxidized in the subsequent step only from the edge surface side thereof. The covering film 91 is provided to hinder oxidation of the upper electrode 80B from the top surface side thereof.

The composition of the covering film 91 is not particularly limited, and the covering film 91 may be any organic film, such as a polymeric film, or any inorganic film. Since the covering film 91 serves to hinder oxidation of the upper electrode 80B from the top surface side thereof, the covering film 91 preferably has a low oxygen permeability coefficient. The covering film 91 may have an oxygen permeability coefficient at 40° C. of less than 1.0×10⁻¹¹ (cm³(STP)·cm/cm²·s·cmHg). The film thickness of the covering film 91 is not particularly limited, and may be designed as appropriate within a range where oxidation of the upper electrode 80B from the top surface side thereof can sufficiently be hindered, depending on the oxygen permeability coefficient of the film.

If the covering film 91 is a polymeric film, the covering film 91 may be formed, for example, through a process including preparing a solution containing the polymer dissolved in a solvent, coating the solution on the upper electrode 80B using one of various printing processes, such as screen printing, and drying the coated solution to remove the solvent. A polymer precursor may be used to form the coated film.

If the covering film 91 is an inorganic film, examples of the process used to form the covering film 91 may include gas phase processes, such as sputtering, CVD, and vapor deposition; and chemical liquid phase processes, such as sol-gel method and MOD (metal organic deposition).

Then, as shown in FIG. 5E, the upper electrode 80B covered with the covering film 91 is oxidized from the edge surface side thereof to provide the edge portion 80E of the upper electrode 80B with the gradient composition structure (step (H)). The oxidation may be achieved by heating under the presence of oxygen, such as oxygen or air, or through an oxygen plasma ashing process, for example.

Finally, as shown in FIG. 5F, the covering film 91 is removed. In this manner, the piezoelectric device 4 of the above-described embodiment is produced. The removal of the covering film 91 is achieved in the same manner as is described for the oxygen permeating film 90 shown in FIGS. 4A to 4F.

It should be noted that the method for producing the piezoelectric device of the second embodiment is not limited to the processes shown in FIGS. 4A to 4F and FIGS. 5A to 5F, and may be modified as appropriate.

### Inkjet Recording Device

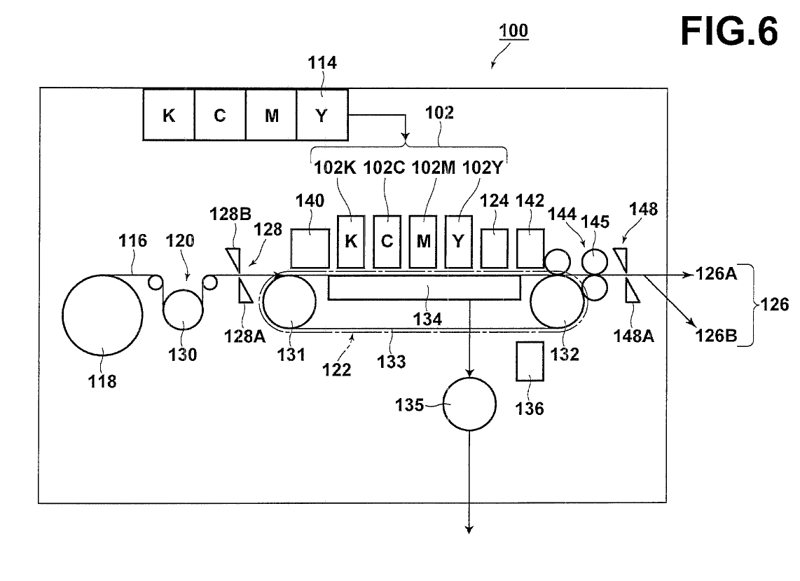

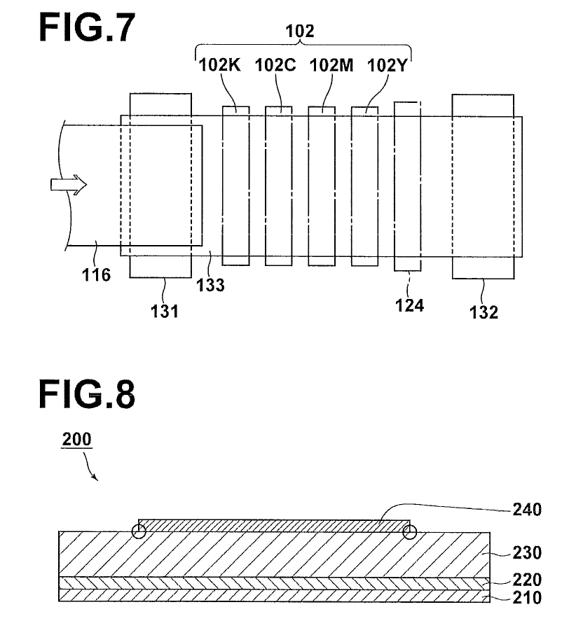

Now, an example configuration of an inkjet recording device including the inkjet recording head 3 or 6 of the above-described embodiments is described with reference to FIGS. 6 and 7. FIG. 6 shows the entire device configuration, and FIG. 7 is a partial plan view of the device.

An inkjet recording device 100 shown in the drawings generally includes: a printing section 102 having a plurality of inkjet recording heads (hereinafter simply referred to as “heads”) 102K, 102C, 102M and 102Y provided correspondingly to ink colors; an ink storing and charging section 114 for storing inks to be fed to the heads 102K, 102C, 102M and 102Y; a paper feeding section 118 for feeding recording paper 116; a decurling section 120 for decurling the recording paper 116; a suction belt conveyer section 122 disposed to face to the nozzle surface (ink discharge surface) of the printing section 102, for conveying the recording paper 116 with keeping the flatness of the recording paper 116; a print detection section 124 for reading the result of printing at the printing section 102; and a paper discharge section 126 for discharging the printed recording paper (a print) to the outside.

Each of the heads 102K, 102C, 102M and 102Y forming the printing section 102 corresponds to the inkjet recording head 3 or 6 of the above-described embodiments.

At the decurling section 120, the recording paper 116 is decurled by a heating drum 130 heating the recording paper 116 in a direction opposite to the direction of the curl.

In the device using the roll paper, a cutter 128 is provided downstream the decurling section 120, as shown in FIG. 6, so that the roll paper is cut by the cutter into a sheet of a desired size. The cutter 128 is formed by a fixed blade 128A, which has a length equal to or larger than the width of the conveyance path for the recording paper 116, and a round blade 128B, which moves along the fixed blade 128A. The fixed blade 128A is disposed on the back surface side of the print, and the round blade 128B is disposed on the print surface side via the conveyance path. In a case where the device uses cut sheets, the cutter 128 is not necessary.

The decurled and cut recording paper sheet 116 is sent to the suction belt conveyer section 122. The suction belt conveyer section 122 includes an endless belt 133 wrapped around rollers 131 and 132, and is adapted such that at least an area of the belt facing the nozzle surface of the printing section 102 and a sensor surface of the print detection section 124 forms a horizontal (flat) surface.

The belt 133 has a width that is larger than the width of the recording paper sheet 116, and a number of suction holes (not shown) are formed in the belt surface. A suction chamber 134 is provided on the inner side of the belt 133 wrapped around the rollers 131 and 132 at a position where the suction chamber 134 faces to the nozzle surface of the printing section 102 and the sensor surface of the print detection section 124. A suction force generated by a fan 135 provides the suction chamber 134 with a negative pressure, thereby holding the recording paper sheet 116 on the belt 133 with suction.

As a motive force from a motor (not shown) is transmitted to at least one of the rollers 131 and 132, around which the belt 133 is wrapped, the belt 133 is driven in the clockwise direction in FIG. 6, and the recording paper sheet 116 held on the belt 133 is conveyed from the left to the right in FIG. 6.

In a case where margin-less printing, or the like, is carried out, the inks adhere on the belt 133. Therefore, a belt cleaning section 136 is provided at a predetermined position (any appropriate position other than the print region) on the outer side of the belt 133.

A heating fan 140 is provided upstream the printing section 102 along the paper sheet conveyance path formed by the suction belt conveyer section 122. The heating fan 140 blows heating air onto the recording paper sheet 116 to heat the recording paper sheet 116 before printing. Heating the recording paper sheet 116 immediately before printing promotes drying of the deposited ink.

The printing section 102 is a so-called full-line head, in which line heads, each having a length corresponding to the maximum paper width, are arranged in a direction (main scanning direction) perpendicular to the paper feed direction (see FIG. 7). Each recording head 102K, 102C, 102M, 102Y is formed by a line head, which has a plurality of ink discharge ports (nozzles) provided across a length that is larger than at least one side of the recording paper sheet 116 of the maximum size printable by the inkjet recording device 100.

The heads 102K, 102C, 102M and 102Y respectively corresponding to the color inks of black (K), cyan (C), magenta (M) and yellow (Y) are disposed in this order from the upstream side along the feed direction of the recording paper sheet 116. By discharging the color inks from the heads 102K, 102C, 102M and 102Y while the recording paper sheet 116 is conveyed, a color image is recorded on the recording paper sheet 116.

The print detection section 124 is formed by a line sensor, or the like, which images the result of ink droplets deposited by the printing section 102, and the image of the deposited ink droplets read by the line sensor is used to detect discharge defects, such as clogging of the nozzles.

A drying section 142 formed, for example, by a heating fan for drying the printed image surface is disposed downstream the print detection section 124. Since contact with the printed surface should be avoided until the printed inks dry, blowing hot air may be preferred.

A heating and pressurizing section 144 for controlling the gloss of the image surface is disposed downstream the drying section 142. At the heating and pressurizing section 144, the image surface is pressed with a pressure roller 145 having a predetermined textured pattern on the surface thereof while the image surface is heated, thereby transferring the textured pattern onto the image surface.

The thus obtained print is discharged at the paper discharge section 126. Prints of intended images (prints on which intended images are printed) and test prints may separately be discharged. The inkjet recording device 100 includes a sorting means (not shown) for sorting the prints of intended images and the test prints and switching the discharge paths to selectively send the prints of intended images and the test prints to a discharge section 126A or 126B.

In a case where an intended image and a test print are printed at the same time on a larger paper sheet, a cutter 148 may be provided to cut off the test print area.

The configuration of the inkjet recording device 100 is as described above.

### Modifications

The invention is not limited to the above-described embodiments, and may be modified as appropriate without departing from the spirit and scope of the invention.

### EXAMPLES

Now, examples according to the invention and a comparative example are described.

### Example 1

A piezoelectric device of the invention was provided in the following manner according to the process shown in FIGS. 2A to 2F.

As a substrate for film formation, a substrate with an electrode was prepared, which included a 30 nm-thick Ti adhesion layer and a 150 nm-thick Pt lower electrode formed on a Si wafer in this order. Then, a 5 μm-thick PZT piezoelectric film was formed using a Pb_{1.3}Zr_{0.52}Ti_{0.48}O₃ target and a RF sputtering apparatus. Film formation conditions were as follows:
substrate temperature: 525° C.,
voltage applied to target: 2.5 W/cm²,
substrate-target distance: 60 mm,
degree of vacuum: 0.5 Pa, and
film formation gas: Ar/O₂ mixed gas (O₂ partial pressure was 1.3 mol %).

Then, a solution containing a polyimide dissolved in a solvent was coated on the piezoelectric film by spin coating, and the coated solution was subjected to a heat treatment at 300° C. for one hour to remove the solvent, thereby forming an unpatterned polyimide insulating layer. The film thickness was 200 nm.

Then, an 8 μm-thick resist mask was formed at an area on the insulating layer where the upper electrode is not formed, and the insulating layer was subjected to dry etching. Etching conditions were as follows:
Ar/CHF₃/CF₄ plasma etching,
pressure: 130 Pa,
Ar flow rate: 800 sccm,
CHF₃ flow rate: 60 sccm,
CF₄ flow rate: 60 sccm,
applied radio frequency wave: 400 kHz,
radio frequency power density: 3 W/cm².

After the dry etching, an insulating layer having a thickness that gradually increases along the direction from the central area toward the edge surface of the upper electrode was left at an edge portion of the area where the upper electrode was to be formed, thereby forming the sloped-thickness insulating layer. The area W2 where the sloped-thickness insulating layer was formed was 5% of the width W1 of the upper electrode (the total width W2 of the sloped-thickness insulating layer at the opposite edges was 10% of the width W1), and the slope angle θ was 60°. The slope angle θ can be controlled by controlling the conditions, such as the gas flow rate and the pressure. For example, by decreasing the gas flow rate and/or increasing the pressure, a smaller slope angle θ can be provided.

Thereafter, the steps shown in FIGS. 2D to 2F were carried out to provide the piezoelectric device of the invention. The upper electrode had a multi-layer structure including a 50 nm-thick Ti layer and a 200 nm-thick Pt layer. The pattern of the upper electrode was a circular pattern with a diameter of 1000 μm.

Since it is difficult to directly measure that the intensity of the electric field exerted on the edge portion of the upper electrode gradually decreases along the direction from the central area toward the edge surface of the upper electrode, a distribution of temperature of heat emitted by the piezoelectric material, which is proportional to the intensity of the electric field, was evaluated to achieve indirect verification. The temperature was measured using a thermo microscope, and a two-dimensional temperature distribution on the surface of the upper electrode under drive conditions of drive voltage of 30V and drive frequency of 100 kHz was evaluated. Since there is no thermal radiation on a metal electrode, a black spray with an emissivity of 0.95 was sprayed over the entire surface of the upper electrode, and a temperature distribution over the entire surface of the upper electrode was measured. As a result, the temperature was 55° C. at the main portion of the upper electrode, whereas, at the edge portion, the temperature gradually decreased along the direction from the central area toward the edge surface of the upper electrode, and the temperature was 25° C. at the edge of the upper electrode. Through the above-described test, it was indirectly confirmed that the gradually decreasing electric field was provided at the edge portion of the upper electrode, as intended.

To the resulting piezoelectric device, a trapezoidal wave was applied under conditions of applied voltage of 50 kV/cm and frequency of 10 kHz in an environment of temperature of 40° C. and relative humidity of 85%, and the number of drive cycles when a dielectric dissipation factor reached 20% was measured to determine a durability life of the piezoelectric device. The durability life was about 30 billion cycles, which was higher than a target durability for practical use of 10 billion cycles.

### Example 2

A piezoelectric device of the invention was provided in the same manner as in Example 1, except that a SiO₂ film was formed as the sloped-thickness insulating layer. The durability life was measured in the same manner as in Example 1, and was found to be about 30 billion cycles, which was higher than the target durability for practical use of 10 billion cycles.

### Example 3

A piezoelectric device of the invention was provided in the following manner according to the process shown in FIGS. 4A to 4F.

A 30 nm-thick Ti adhesion layer, a 150 nm-thick Pt lower electrode and a 5 μm-thick PZT piezoelectric film were formed in this order on a Si wafer in the same manner as in Example 1. Then, a Cr film was formed on the piezoelectric film to form a 300 nm-thick unpatterned upper electrode having a uniform composition, and then patterning of the upper electrode was carried out using a resist mask.

Then, on the upper electrode, a polyethylene oxygen permeating film (oxygen permeability coefficient=1.5×10⁻¹⁰ (cm³(STP)·cm/cm²·s·cmHg)) having the sloped-thickness structure, where the area corresponding to the main portion of the upper electrode has a uniform thickness and the area corresponding to the edge portion of the upper electrode has a thickness that gradually decreases along the direction from the central area toward the edge surface of the upper electrode, was formed. The maximum film thickness of the polyethylene oxygen permeating film was 50 μm.

Then, the upper electrode covered with the oxygen permeating film was subjected to oxidation. The oxidation was achieved through a heat treatment at 50° C. under oxygen flow atmosphere. With this treatment, the edge portion of the upper electrode was provided with the gradient composition structure where a metal oxide content gradually increased along the direction from the central area toward the edge surface of the upper electrode.

In order to check whether the intended composition gradient was provided at the edge portion of the upper electrode, quantification analysis of oxidation degree was conducted through EDX (energy dispersive X-ray microanalysis). At the edge portion of the upper electrode, a peak intensity indicating CrOₓ (chromium oxide) gradually increased from 0 to 1 along the direction from the central area toward the edge surface of the upper electrode, and thus it was confirmed that the oxidation degree gradually increased. The area W3 where the gradient composition structure was formed was 5% of the width W1 of the upper electrode (the total width W3 of the gradient composition structure at the opposite edges was 10% of W1).

Finally, the oxygen permeating film was removed by being dissolved with a solvent, thereby providing the piezoelectric device of the invention.

Using a thermo microscope, whether the intensity of the electric field exerted on the piezoelectric material at the edge portion of the upper electrode gradually decreased along the direction from the central area toward the edge surface of the upper electrode was indirectly evaluated in the same manner as in Example 1. The temperature distribution was measured in the same manner as in Example 1 under drive conditions of drive voltage of 30 V and drive frequency of 100 kHz. The temperature was 55° C. at the main portion of the upper electrode, whereas, at the edge portion, the temperature gradually decreased along the direction from the central area toward the edge surface of the upper electrode, and the temperature was 25° C. at the edge of the upper electrode.

The durability life was measured in the same manner as in Example 1, and was found to be about 30 billion cycles, which was higher than the target durability for practical use of 10 billion cycles.

### Example 4

A piezoelectric device of the invention was provided in the same manner as in Example 3, except that the upper electrode was an Ir electrode. Similarly to Example 3, the formed upper electrode had the gradient composition structure. The durability life was measured in the same manner as in Example 1, and was found to be about 30 billion cycles, which was higher than the target durability for practical use of 10 billion cycles.

### Example 5

A piezoelectric device of the invention was provided in the following manner according to the process shown in FIGS. 5A to 5F.

A 30 nm-thick Ti adhesion layer, a 150 nm-thick Pt lower electrode and a 5 μm-thick PZT piezoelectric film were formed in this order on a Si wafer in the same manner as in Example 1. Then, a Cr film was formed on the piezoelectric film to form a 300 nm-thick unpatterned upper electrode having a uniform composition, and then patterning of the upper electrode was carried out using a resist mask.

Then, on the upper electrode, a polyacrylonitrile film, which had a uniform thickness and low oxygen permeability, i.e., high oxygen barrier function (film thickness was 1 μm, oxygen permeability coefficient was 8×10⁻¹⁶ (cm³(STP)·cm/cm²·s·cmHg)), was formed as the covering film.

Then, the upper electrode covered with the covering film was subjected to oxidation. The oxidation was achieved through a heat treatment at 50° C. under oxygen flow atmosphere. With this treatment, the edge portion of the upper electrode was provided with the gradient composition structure where a metal oxide content gradually increased along the direction from the central area toward the edge surface of the upper electrode.

In order to check whether the intended composition gradient was provided at the edge portion of the upper electrode, quantification analysis of oxidation degree was conducted through EDX (energy dispersive X-ray microanalysis), in the same manner as in Example 3. At the edge portion of the upper electrode, a peak intensity indicating CrOₓ (chromium oxide) gradually increased from 0 to 1 along the direction from the central area toward the edge surface of the upper electrode, and thus it was confirmed that the oxidation degree gradually increased. The area W3 where the gradient composition structure was formed was 5% of the width W1 of the upper electrode (the total width W3 of the gradient composition structure at the opposite edges was 10% of W1).

Finally, the covering film was removed by being dissolved with a solvent, thereby providing the piezoelectric device of the invention.

Using a thermo microscope, whether the intensity of the electric field exerted on the piezoelectric material at the edge portion of the upper electrode gradually decreased along the direction from the central area toward the edge surface of the upper electrode was indirectly evaluated in the same manner as in Example 1. The temperature distribution was measured in the same manner as in Example 1 under drive conditions of drive voltage of 30 V and drive frequency of 100 kHz. The temperature was 55° C. at the main portion of the upper electrode, whereas, at the edge portion, the temperature gradually decreased along the direction from the central area toward the edge surface of the upper electrode, and the temperature was 25° C. at the edge of the upper electrode.

The durability life was measured in the same manner as in Example 1, and was found to be about 30 billion cycles, which was higher than the target durability for practical use of 10 billion cycles.

### Comparative Example 1

A 30 nm-thick Ti adhesion layer, a 150 nm-thick Pt lower electrode and a 5 μm-thick PZT piezoelectric film were formed in this order on a Si wafer in the same manner as in Example 1. Thereafter, the upper electrode was patterned through a conventional photolithography process to provide a piezoelectric device of a comparative example. The upper electrode had a multi-layer structure including a 50 nm-thick Ti layer and a 200 nm-thick Pt layer. The pattern of the upper electrode was a circular pattern with a diameter of 1000 μm.

The durability life was measured in the same manner as in Example 1, and was found to be about 5 billion cycles, which was lower than the target durability for practical use of 10 billion cycles.

### INDUSTRIAL APPLICABILITY

The piezoelectric device and the method for producing the piezoelectric device of the invention are preferably applicable to piezoelectric actuators provided in inkjet recording heads, magnetic read/write heads, MEMS (Micro Electro-Mechanical Systems) devices, micropumps, ultrasound probes, ultrasound motors, etc., and ferroelectric devices, such as ferroelectric memory.

What is claimed is:

1. A piezoelectric device comprising a piezoelectric material and lower and upper electrodes for applying an electric field to the piezoelectric material, wherein
the upper electrode is patterned, and
an edge portion of the upper electrode comprises a structure where an intensity of the electric field exerted on the piezoelectric material gradually decreases along a direction from a central portion toward an edge surface of the upper electrode when the electric field is applied to the piezoelectric material.

2. The piezoelectric device as claimed in claim 1 further comprising a sloped-thickness insulating layer formed between the piezoelectric material and the edge portion of the upper electrode, the sloped-thickness insulating layer having a thickness that gradually increases along the direction from the central area toward the edge surface of the upper electrode.

3. The piezoelectric device as claimed in claim 2, wherein the sloped-thickness insulating layer comprises a material having thickness-dependent permittivity.

4. The piezoelectric device as claimed in claim 3, wherein the sloped-thickness insulating layer comprises an organic insulating layer mainly composed of polyimide or an inorganic insulating layer mainly composed of a Si compound.

5. The piezoelectric device as claimed in claim 2 produced by a method comprising:
step (A) of forming an unpatterned insulating layer on a substrate having the lower electrode and the piezoelectric material formed thereon;
step (B) of forming a resist mask on the insulating layer at an area where the upper electrode is not to be formed; and
step (C) of partially removing the insulating layer from an area where the upper electrode is to be formed to leave the insulating layer at an edge portion of the area where the upper electrode is to be formed, the left insulating layer having a thickness that gradually increases along the direction from the central area toward the edge surface of the upper electrode, thereby forming the sloped-thickness insulating layer.

6. The piezoelectric device as claimed in claim 5, wherein the step (C) comprises partially removing the insulating layer from the area where the upper electrode is to be formed through a dry etching process.

7. The piezoelectric device as claimed in claim 1, wherein the edge portion of the upper electrode comprises a gradient composition structure where an insulation property of the upper electrode gradually becomes higher along the direction from the central area toward the edge surface of the upper electrode.

8. The piezoelectric device as claimed in claim 7, wherein
a main portion other than the edge portion of the upper electrode is mainly composed of a conductive metal, and
the edge portion of the upper electrode comprises a gradient composition structure where a metal oxide content gradually increases along the direction from the central area toward the edge surface of the upper electrode.

9. The piezoelectric device as claimed in claim 8 produced by a method comprising:
step (D) of forming the upper electrode having a uniform composition mainly composed of a conductive metal on a substrate having the lower electrode and the piezoelectric material formed thereon;
step (E) of forming an oxygen permeating film on the upper electrode, the oxygen permeating film having such oxygen permeability that an area of the oxygen permeating film corresponding to the main portion other than the edge portion of the upper electrode has a uniform oxygen transmission rate, and an area of the oxygen permeating film corresponding to the edge portion of the upper electrode has an oxygen transmission rate that gradually increases along the direction from the central area toward the edge surface of the upper electrode; and
step (F) of applying oxidation to the upper electrode covered with the oxygen permeating film to provide the edge portion of the upper electrode with the gradient composition structure.

10. The piezoelectric device as claimed in claim 9, wherein the step (E) comprises forming, as the oxygen permeating film, an oxygen permeating film having a sloped-thickness structure where an area of the oxygen permeating film corresponding to the main portion other than the edge portion of the upper electrode has a uniform thickness, and an area of the oxygen permeating film corresponding to the edge portion of the upper electrode has a thickness that gradually decreases along the direction from the central area toward the edge surface of the upper electrode.

11. The piezoelectric device as claimed in claim 10, wherein the oxygen permeating film comprises a film having an oxygen permeability coefficient at a temperature of 40° C. of not less than 1.0×10⁻¹¹ (cm³(STP)·cm/cm²·s·cmHg).

12. The piezoelectric device as claimed in claim 8 produced by a method comprising:
step (D) of forming the upper electrode having a uniform composition mainly composed of a conductive metal on a substrate having the lower electrode and the piezoelectric material formed thereon;
step (G) of forming a covering film on the upper electrode; and
step (H) of applying oxidation to the upper electrode covered with the covering film from an edge surface side of the upper electrode to provide the edge portion of the upper electrode with the gradient composition structure.

13. A method for producing a piezoelectric device, the method producing the piezoelectric device of claim 2, the method comprising:
step (A) of forming an unpatterned insulating layer on a substrate having the lower electrode and the piezoelectric material formed thereon;
step (B) of forming a resist mask on the insulating layer at an area where the upper electrode is not to be formed; and
step (C) of partially removing the insulating layer from an area where the upper electrode is to be formed to leave the insulating layer at an edge portion of the area where the upper electrode is to be formed, the left insulating layer having a thickness that gradually increases along the direction from the central area toward the edge surface of the upper electrode, thereby forming the sloped-thickness insulating layer.

14. The method for producing a piezoelectric device as claimed in claim 13, wherein the step (C) comprises partially removing the insulating layer from the area where the upper electrode is to be formed through a dry etching process.

15. A method for producing a piezoelectric device, the method producing the piezoelectric device of claim 8, the method comprising:
step (D) of forming the upper electrode having a uniform composition mainly composed of a conductive metal on a substrate having the lower electrode and the piezoelectric material formed thereon;
step (E) of forming an oxygen permeating film on the upper electrode, the oxygen permeating film having such oxygen permeability that an area of the oxygen permeating film corresponding to the main portion other than the edge portion of the upper electrode has a uniform oxygen transmission rate, and an area of the oxygen permeating film corresponding to the edge portion of the upper electrode has an oxygen transmission rate that gradually increases along the direction from the central area toward the edge surface of the upper electrode; and
step (F) of applying oxidation to the upper electrode covered with the oxygen permeating film to provide the edge portion of the upper electrode with the gradient composition structure.

16. The method for producing a piezoelectric device as claimed in claim 15, wherein the step (E) comprises forming, as the oxygen permeating film, an oxygen permeating film having a sloped-thickness structure where an area of the oxygen permeating film corresponding to the main portion other than the edge portion of the upper electrode has a uniform thickness, and an area of the oxygen permeating film corresponding to the edge portion of the upper electrode has a thickness that gradually decreases along the direction from the central area toward the edge surface of the upper electrode.

17. The method for producing a piezoelectric device as claimed in claim 16, wherein the step (E) comprises forming, as the oxygen permeating film, a film having an oxygen permeability coefficient at a temperature of 40° C. of not less than 1.0×10⁻¹¹ (cm³(STP)·cm/cm²·s·cmHg).

18. A method for producing a piezoelectric device, the method producing the piezoelectric device of claim 8, the method comprising:
step (D) of forming the upper electrode having a uniform composition mainly composed of a conductive metal on a substrate having the lower electrode and the piezoelectric material formed thereon;
step (G) of forming a covering film on the upper electrode; and
step (H) of applying oxidation to the upper electrode covered with the covering film from an edge surface side of the upper electrode to provide the edge portion of the upper electrode with the gradient composition structure.

19. A liquid discharge device comprising:
the piezoelectric device as claimed in claim 1; and
a liquid discharge member disposed adjacent to the piezoelectric device, the liquid discharge member comprising a liquid reservoir for storing a liquid, and a liquid discharge port for discharging the liquid from the liquid reservoir to the outside in response to application of the electric field to the piezoelectric material.
